(19) United States
(12) Patent Application Publication
(10) Pub. No.: US 2009/0094507 A1
(43) Pub. Date: Apr. 9, 2009

(54) CODE ERROR DETECTOR AND ERROR DETECTING CODE GENERATOR

(75) Inventor: Wakako Nakase, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: Oki Electric Industry Co., Ltd., Tokyo (JP)

(21) Appl. No.: 12/194,561

(22) Filed: Aug. 20, 2008

(30) Foreign Application Priority Data
Oct. 4, 2007 (JP) 2007260644

(51) Int. Cl. H03M 13/05; G06F 11/10

(52) U.S. Cl. 714/807; 714/E11.032

(57) ABSTRACT

A code error detector includes an input data generator and a code calculator. The input data generator divides received data into a plurality of data blocks, each including the same number of code bits as a predetermined number of parallel processes. The code calculator receives, as a parallel input, the code bits of each of the data blocks and applies a parallel calculation based on a predetermined generator polynomial on the data blocks to perform an error detection process. When a bit is missing from any of the data blocks, the input data generator inserts a dummy bit into a bit position of the missing bit.

### BACKGROUND OF THE INVENTION

1. Field of the Invention

The present invention generally relates to a technology for detecting code errors that occur in data, and more particularly to a process for generating error detecting codes and a process for detecting code errors through parallel calculations.

2. Description of the Related Art

A code, which is designed to detect a code error that occurs in transmission data in a transport path, is referred to as an error detecting code. For example, a Cyclic Redundancy Check (CRC) code is widely used as the error detecting code. A code having a code length of “n” and an information length of “k” is referred to as a (n,k) code. Encoding based on the CRC scheme can be performed by calculating the product of x^{n-k} and an information polynomial M(x), which has coefficients corresponding to the value of information bits to be transmitted, and dividing the resulting product by a generator polynomial G(x) to generate a residue polynomial R(x). Here, a codeword to be transmitted is represented by a code polynomial U(x)=M(x)·x^{n-k}+R(x). A process of detecting errors in a received word can be performed by determining whether or not a received polynomial representing the received word is divisible by the generator polynomial G(x) since the code polynomial U(x) is divisible by the generator polynomial G(x).

A CRC calculation circuit that performs such encoding and error detecting can be easily realized using a shift register including a plurality of delay elements which are connected in cascade (for example, see Hideki Imai, “Code Theory”, Institute of Electronics, Information and Communication Engineers (IEICE), published on Mar. 15, 1990, pp. 113-120). If the received word contains a code error, at least one of the delay elements of the shift register of the CRC calculation circuit provided at the receiving side will hold a value other than “0” as a result of the residue calculation. This allows detection of the code error. Since the shift register of the CRC calculation circuit serially processes a sequence of bits in cycle times of the operating clock, the shift register requires a calculation process time that is suited for the bit length of the received data. If the calculation process must be performed rapidly due to a high data transfer rate, the calculation process time can be reduced by increasing the frequency of the operating clock. However, an increase in the frequency of the operating clock results in an increase in power consumption.

Another approach for reducing the calculation process time is to process input data through parallel calculations. This processing is applied to a plurality of bits in parallel. A CRC calculation circuit having a shift register which performs parallel calculations is described in Japanese Patent Application Publication (Kokai) No. 9-18354.

### SUMMARY OF THE INVENTION

In order to perform parallel calculations on data, the conventional calculation circuit converts serially-input data into the same number of parallel bit sequences as the number of parallel processes of the shift register and supplies the bit sequences in parallel to the shift register. The bit length of the input data must be a multiple of the number of parallel processes of the shift register. That is, when the number of parallel processes of the shift register is N and the input data is M bits long, M must be divisible by N. However, if the input data has a variable or prime bit length, the conventional calculation circuit will provide an erroneous calculation result since the bit length of the input data is indivisible by the number of parallel processes of the shift register.

One object of the present invention is to provide a code error detector which can detect a code error in received data through parallel calculations even when the received data has a variable or prime bit length.

Another object of the present invention is to provide an error detecting code generator which can generate an error detecting code for data-to-be-transmitted through parallel calculations even when the data-to-be-transmitted has a variable or prime bit length.

According to one aspect of the present invention, there is provided an improved code error detector for detecting a code error in received data. The received data has information and check bits. The code error detector includes an input data generator for dividing the received data into a plurality of data blocks. Each data block has the same number of code bits as a predetermined number of parallel processes. The input data generator sequentially outputs the data blocks. The code error detector also includes a code calculator for receiving, as a parallel input, the code bits of each of the data blocks sequentially supplied from the input data generator and performing a parallel calculation based on a predetermined generator polynomial on the data blocks to carry out an error detection process. When any of the data blocks has a missing bit (or missing bits), i.e., when any bit is missing, the input data generator inserts a dummy bit (or dummy bits) into a bit position (or bit positions) of the missing bit (or missing bits).

Even when the received data has a variable or prime bit length, the code error detector is able to detect a code error in the received data because dummy bits are inserted into bit positions of missing bits in the data blocks of the received data. Thus, it is always possible to detect a code error, regardless of the bit length of the received data.

According to another aspect of the present invention, there is provided an error detecting code generator for generating a codeword sequence that allows detection of a code error in transmission data. The error detecting code generator includes an input data generator for dividing data-to-be-transmitted into a plurality of data blocks. Each data block has the same number of information bits as a predetermined number of parallel processes. The input date generator sequentially outputs the data blocks. The error detecting code generator also includes a code calculator for receiving, as a parallel input, the information bits of each of the data blocks sequentially supplied from the input data generator and performing a parallel calculation based on a predetermined generator polynomial on the data blocks to generate check bits. The error detecting code generator also includes a transmission data generator for generating a codeword sequence including the information and check bits. When any of the data blocks has one or more missing bits, i.e., when any bit is missing, the input data generator inserts a dummy bit (or dummy bits) into a bit position (or positions) of the missing bit(s).

Even when the data-to-be-transmitted has a variable or prime bit length, the error detecting code generator of the invention can generate an error detecting code for the data-to-be-transmitted since dummy bits are inserted into bit positions of missing bits in the data blocks of the data-to-be-transmitted. Therefore, it is always possible to generate an error detecting code, regardless of the bit length of the data-to-be-transmitted.

### BRIEF DESCRIPTION OF THE DRAWINGS

These and other objects, aspects and advantages of the present invention will be more clearly understood from the following detailed description and appended claims when read and understood in conjunction with the accompanying drawings, in which:

FIG. 1 is a block diagram illustrating a schematic configuration of a code error detector according to an embodiment of the invention;

FIG. 2 illustrates an example operation of a code calculator included in the code error detector shown in FIG. 1;

FIG. 3A illustrates an example of received data;

FIG. 3B illustrates a group of data blocks into which the received data is divided;

FIG. 4 illustrates how data blocks are sequentially introduced to the code calculator of FIG. 2;

FIG. 5A illustrates an example configuration of an initial value setter included in the code error detector of FIG. 1;

FIG. 5B illustrates example contents of an initial value table used in the initial value setter;

FIG. 6 is a block diagram illustrating a schematic configuration of a calculation controller included in the code error detector of FIG. 1;

FIG. 7 is a block diagram illustrating a schematic configuration of an error detecting code generator according to an embodiment of the invention; and

FIG. 8 illustrates an example configuration of a code calculator included in the error detecting code generator of FIG. 7.

### DETAILED DESCRIPTION OF THE INVENTION

Reference will now be made to various embodiments of the invention.

It should be noted that an expression “data block has a missing bit” means that a certain bit is missing from the data block in this specification.

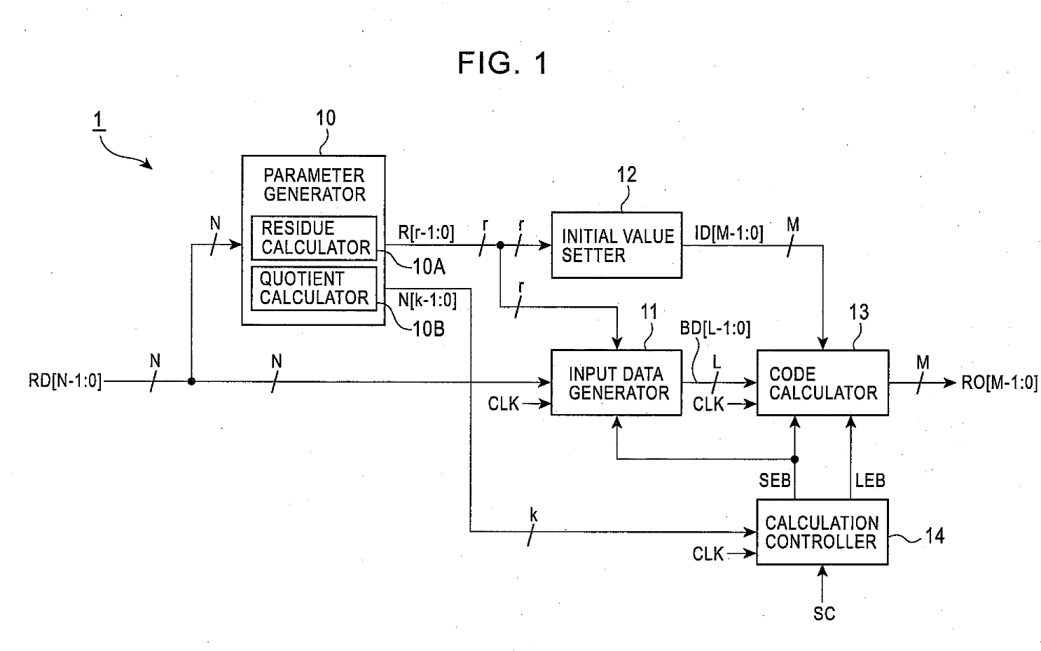

Referring first to FIG. 1, a configuration of a code error detector 1 according to an embodiment of the invention will be described. As shown in FIG. 1, the code error detector 1 includes a parameter generator 10, an input data generator 11, an initial value setter 12, a code calculator 13, and a calculation controller 14. The code error detector 1 is embedded in a receiver (not shown). The receiver has a demodulator (not shown) and receives a signal. In the receiver, the demodulator demodulates a signal received from a transport path to obtain data RD [N−1:0] which is N bits long (where N is a positive integer). The data RD [N−1:0] is introduced to the code error detector 1. The data RD [N−1:0] includes a received word having information bits and check bits based on the CRC scheme. The received word represents coefficients of a received polynomial C(x). The received polynomial C(x) is divisible by a generator polynomial G(x) when the received word contains no code error while the received polynomial C(x) is indivisible by the generator polynomial G(x) when the received word contains a code error. For example, the generator polynomial G(x) may be, but is not limited to, G(x)=x¹⁶+x¹²+x⁵+1 in a Galois field GF(2) according to the ITU-T recommendation or G(x)=x¹⁶+x¹⁵+x²+1 in a Galois field GF(2) according to the ANSI specifications.

The input data generator 11 divides the received data RD [N−1:0] into a plurality of data blocks, each of which includes the same number of code bits as the number of parallel processes L of the code calculator 13 (where L is a positive integer greater than one), and sequentially transmits each data block BD [L−1:0] to the code calculator 13. For example, when the received data RD [N−1:0] is 402 bits long and the number of parallel processes of the code calculator 13 is 4 (i.e., L=4), the input data generator 11 divides the data RD [N−1:0] into 101 data blocks. Although the N-bit data RD [N−1:0] is supplied in parallel to the code error detector 1 in this embodiment, the invention is not limited in this regard. For example, the code error detector 1 may have an alternative structure in which the code bits of the data RD [N−1:0] are serially supplied and the input data generator 11 processes the serial input to generate data blocks BD [L−1:0].

The code calculator 13 applies parallel calculations, based on the generator polynomial G(x), on the data blocks to perform an error detection process. That is, the code calculator 13 receives, as a parallel input, L code bits BD [L−1], BD [L−2], . . . , BD [0] of each data block BD [L−1:0] supplied from the input data generator 11 and then applies a parallel calculation on the data block to perform an error detection process. The code calculator 13 is a divider circuit including a shift register (not shown). This shift register includes M delay elements (where M is a positive integer), at least one modulo-2 adder (exclusive OR operator), and a feedback connection. The M delay elements shift the parallel-input code bits BD [L−1], BD [L−2], . . . , BD [0] in parallel synchronously with an operating clock CLK. Residue calculation is performed through shift operations of the shift register in such a manner that the received polynomial C(x) is divided by the generator polynomial G(x) to obtain a residue polynomial R(x). As a result of the residue calculation, the group of delay elements of the shift register holds a bit sequence RO [M−1:0] which represents coefficients of the residue polynomial R(x). The code calculator 13 generates (issues) the bit sequence RO [M−1:0] as a-calculation result. No code error is detected if all bit values of the bit sequence RO [M−1:0] are “0.” A code error is detected if at least one of the bit values of the bit sequence RO [M−1:0] is “1”.

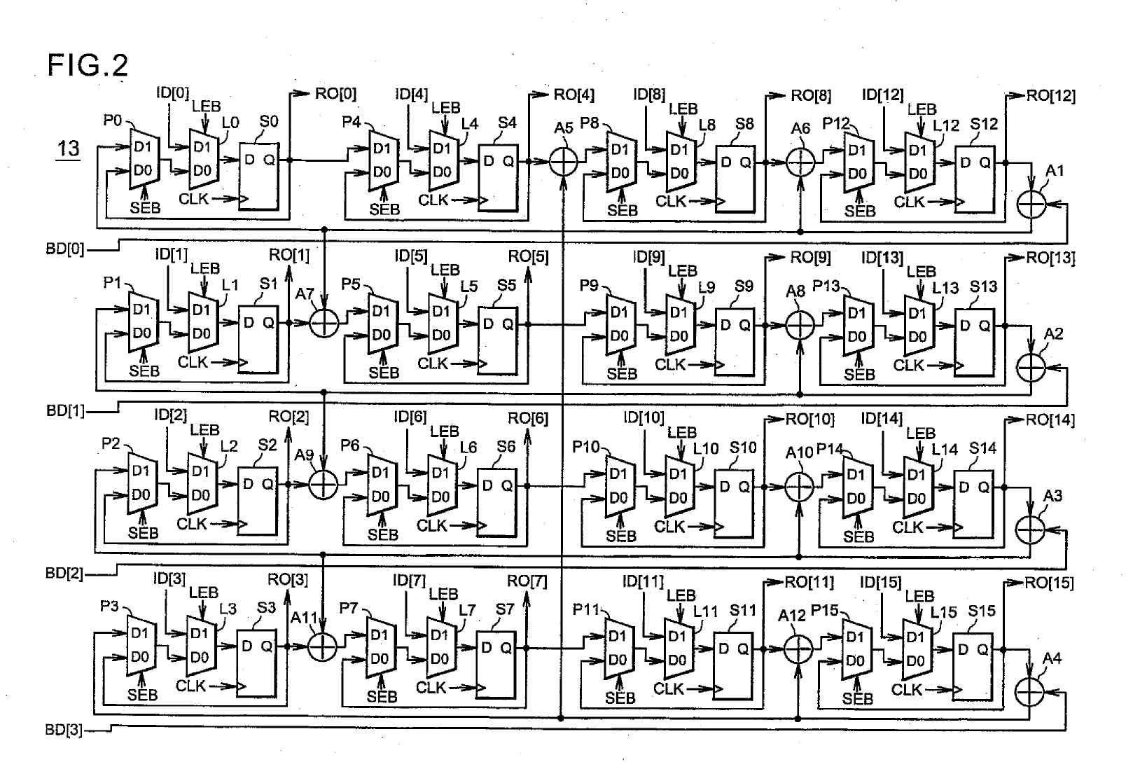

Referring to FIG. 2, the structure of the code calculator 13 is illustrated. FIG. 2 also shows the operation of the code calculator 13 when the number of parallel processes is 4 and the generator polynomial G(x) is x¹⁶+x¹²+x⁵+1. The code calculator 13 receives the 0th (least significant) to 3rd bits BD [0] to BD [3] of a data block BD [3:0] as a parallel input. Specifically, the 0th (least significant) bit BD [0] is sent to an adder A1, the 1st bit BD [1] is sent to an adder A2, the 2nd bit BD [2] is sent to an adder A3, and the 3rd bit BD [3] is sent to an adder A4.

In the code calculator 13 of FIG. 2, four delay elements (flip-flops) S0, S4, S8, and S12 are connected in cascade via selectors P0, L0, P4, L4, PB, L8, P12, and L12 and modulo-2 adders A5 and A6. A feedback connection is provided to feed an output of the delay element S12 to the delay element S0, the adder A6, and an adder A7 via the adder A1. Another four delay elements (flip-flops) S1, S5, S9, and S13 are connected in cascade via selectors P1, L1, P5, L5, P9, L9, P13, and L13 and modulo-2 adders A7 and A8. A feedback connection is provided to feed an output of the delay element S13 to the delay element S1, the adder A8, and an adder A9 via the adder A2. Another four delay elements (flip-flops) S2, S6, S10, and S14 are connected in cascade via selectors P2, L2, P6, L6, P10, L10, P14, and L14 and modulo-2 adders A9 and A10. A feedback connection is provided to feed an output of the delay element S14 to the delay element S2, the adder A10, and an adder A11 via the adder A3. Another four delay elements (flip-flops) S3, S7, S11, and S15 are connected in cascade via selectors P3, L3, P7, L7, P11, L11, P15, and L15 and modulo-2 adders A11 and A12. A feedback connection is provided to feed an output of the delay element S15 to the delay element S3, the adder A12, and the adder A5 via the adder A4.

As shown in FIG. 1, the received data RD [N−1:0] is supplied to the parameter generator 10. The parameter generator 10 detects a bit length “N” of the data RD [N−1:0]. The parameter generator 10 includes a residue calculator 10A and a quotient calculator 10B. The residue calculator 10A calculates a residue (first parameter) by dividing the bit length “N” by the number of parallel processes ‘L.’ The quotient calculator 10B calculates a quotient (second parameter) by dividing the bit length “N” by the number of parallel processes “L.” The r-bit residue data R [r−1:0] representing the residue of the division is sent to the initial value setter 12 and the input data generator 11, while k-bit quotient data N [k−1:0] representing the quotient of the division is sent to the calculation controller 14.

As illustrated in FIG. 1, the residue data R [r−1:0] is provided to the initial value setter 12. The initial value setter 12 includes an initial value table (conversion table) that stores fixed-length bit sequences corresponding respectively to possible values of the residue data R [r−1:0]. Before parallel calculations by the code calculator 13, the initial value setter 12 refers to the initial value table to select a fixed-length bit sequence corresponding to the value of the residue data R [r−1:0]. Then, the initial value setting circuit 12 supplies the selected fixed-length bit sequence (i.e., initial value data ID [M−1:0]) to the code calculator 13. The code calculator 13 performs parallel calculations after performing initial setting by storing the initial value data ID [M−1:0] in the group of delay elements of the shift register.

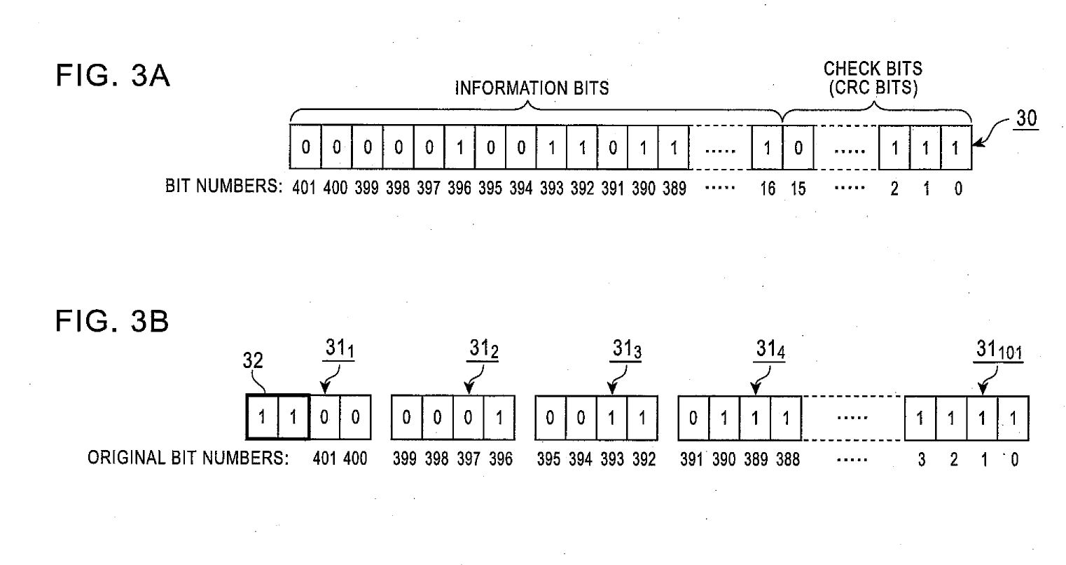

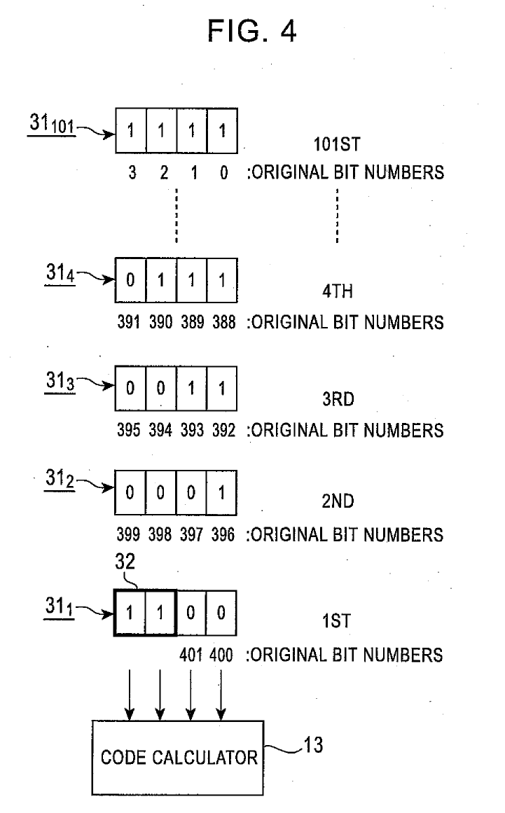

The value of the residue data R [r−1:0] represents the bit length of missing bits that may be missing from a data block BD [L−1:0] generated by the input data generator 11. For example (see FIG. 3A), when the received data 30 is 402 bits long and the number of parallel processes is 4, bits of 2-bit length are missing in one of the data blocks generated by the input data generator 11 since the bit length “402” is indivisible by the number of parallel processes “4”. The code calculator 13 generates an erroneous detection result if it performs parallel calculations on a group of data blocks having missing bits since the value of the missing bits is not constant. In order to prevent such erroneous detection, the input data generator 11 inserts dummy bits of the same bit length (i.e., the same number) as the value of the residue data R [r−1:0] into bit positions of the missing bits. Dividing the received data 30 shown in FIG. 3A generates 101 data blocks 31₁, to 31₁₀₁ as shown in FIG. 3B. The input data generator 11 may allocate missing bits to the 2 most significant bits of the first data block 31₁ and may insert dummy bits 32 having a value of “11” into bit positions of the missing bits. Then, the data blocks 31₁ to 31₁₀₁ are sequentially introduced to the code calculator 13 as shown in FIG. 4.

In order to prevent the above-mentioned erroneous detection, the code calculator 13 also needs to perform initial setting by storing an initial value that matches the dummy bits in the delay element group of the shift register before performing parallel calculations. The initial value setting circuit 12 selects the initial value according to the length of the dummy bits.

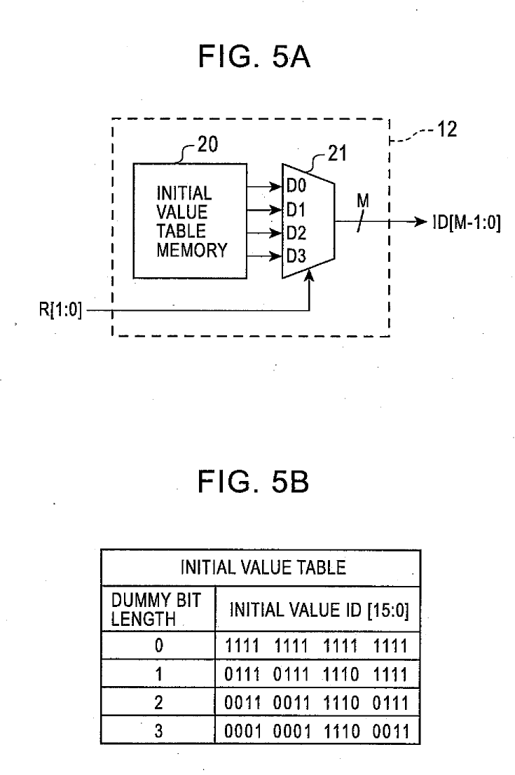

Referring now to FIG. 5A, a configuration of the initial value setting circuit 12 will be described. The initial value setting circuit 12 includes an initial value table memory 20 and a selector 21. The initial value table memory 20 stores initial values which are to be set in the group of delay elements of the shift register of the code calculator 13. The initial value table memory 20 supplies initial values, which include four fixed-length bit sequences corresponding to the number of parallel processes “4”, in parallel to the selector 21. The selector 21 selects one of its inputs D0 to D3 according to the value of the residue data R [1:0] and outputs a fixed-length bit sequence (i.e., initial value data ID [M−1:0]) received through the selected input. FIG. 5B illustrates an example of the initial value table stored in the initial value table memory 20. As shown in FIG. 5B, the initial value table stores initial values (binary values) corresponding respectively to values of the residue data R [1:0], i.e., dummy bit lengths (decimal values).

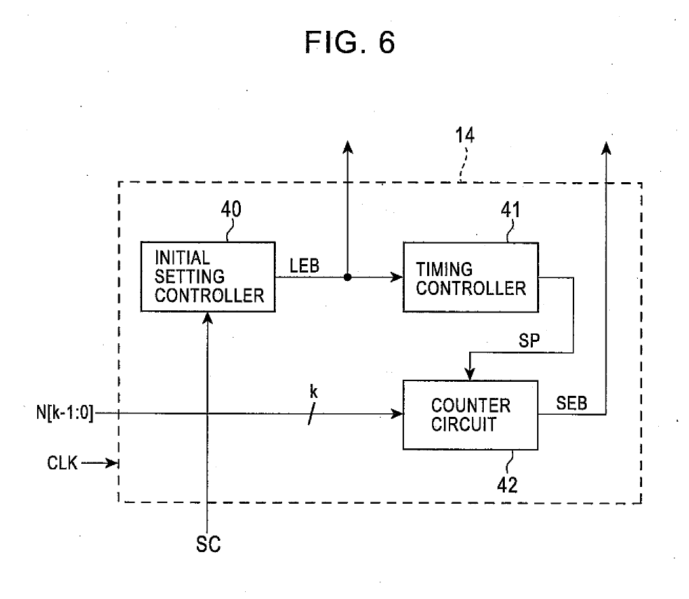

Referring to FIG. 6, a configuration of the calculation controller 14 will be described. The calculation controller 14 includes an initial setting controller 40, a timing controller 41, and a counter circuit (shift controller) 42. These processing blocks 40 to 42 operate synchronously with the operating clock CLK. The initial setting controller 40 generates an initial setting control signal LEB having a certain logic level (for example, a high level) which enables initial setting of the code calculator 13 according to a calculation start command SC received from a host controller (not shown). The code calculator 13 performs initial setting by storing the value of the initial value data ID [M−1:0] provided from the initial value setter 12 in the group of delay elements of the shift register in response to the initial setting control signal LEB received from the calculation controller 14. After the initial setting is completed, i.e., after a particular processing cycle(s) elapse(s), the initial setting controller 40 switches the logic level of the initial setting control signal LEB from the enable level to a disable level (for example, a low level) which disables the initial setting.

When the initial setting control signal LEB received from the initial setting controller 40 switches to the disable level, the timing controller 41 supplies a start pulse SP to the counter circuit 42. Upon receiving the start pulse SP, the counter circuit 42 starts the counting operation that is synchronized with the operating clock CLK. As shown in FIG. 6, the counter circuit 42 receives the quotient data N [k−1:0] from the parameter generator 10. The value of the quotient data N [k−1:0] represents the number of data blocks generated by the input data generator 11. The code calculator 13 performs the same number of parallel calculations as the number of data blocks. Therefore, the value of the quotient data N [k−1:0] can be assumed to be proportional to the number of calculations performed at the code calculator 13.

Until the counter value reaches the value of the quotient data N [k−1:0], the counter circuit 42 generates a shift control signal SEB having an enable level (high level) which enables parallel calculations of the code calculator 13. The input data generator 11 sends the data blocks BD [L−1:0] to the code calculator 13 while the shift control signal SEB having the enable level is given to the code calculator 13. The code calculator 13 can perform parallel calculations while the shift control signal SEB having the enable level is supplied to the code calculator 13.

On the other hand, after the counter value reaches the value of the quotient data N [k−1:0], the counter circuit 42 switches the logic level of the shift control signal SEB to a disable level (for example, a low level) which disables parallel calculations of the code calculator 13. The input data generator 11 stops supplying the data blocks BD [L−1:0] to the code calculator 13 when it receives the shift control signal SEB having the disable level from the calculation controller 14. The code calculator 13 stops parallel calculations in response to the shift control signal SEB having the disable level. Accordingly, shift operations of the shift register in the code calculator 13 are enabled over processing cycles according to the number of calculations. This allows the bode calculator 13 to provide reliable detection results.

If the code calculator 13 is constructed as shown in FIG. 2, a shift control signal SEB having a disable level and an initial setting control signal LEB having an enable level are supplied to the code calculator 13 before the code calculator 13 performs parallel calculations. All the selectors P0 to P15 for shift operations select their inputs D0 to which the outputs of the delay elements S0 to S15 corresponding to the selectors P0 to P15 are fed back. In addition, all the selectors L0 to L15 for initial value setting select their inputs D1 which receive the bits ID [0] to ID [15] of the initial value data ID [15:0] corresponding to the selectors L0 to L15. This allows the selectors L0 to L15 (selection circuit) to store the value of the initial value data ID [15:0] in the associated delay elements S0 to S15.

After initial setting is completed, a shift control signal SEB having an enable level and an initial setting control signal LEB having a disable level are introduced to the code calculator 13. Here, all the selectors P0 to P15 for shift operations select their inputs D1 and all the selectors L0 to L15 for initial value setting select their inputs D0. This allows the code calculator 13 to perform parallel calculations through shift operations. After parallel calculations are finished, a shift control signal SEB having a disable level and an initial setting control signal LEB having a disable level are supplied to the code calculator 13. Here, all the selectors P0 to P15 for shift operations select the inputs D0 to stop shift operations, and all the selectors L0 to L15 for initial value setting select the inputs D0 to allow the delay elements S0 to S15 to keep their values constant.

As described above, even when the received data RD [N−1:0] has a variable or prime bit length, the code error detector 1 of this embodiment can detect a code error in the data RD [N−1:0], regardless of the bit length of the data RD [N−1:0]. This is because the data RD [N−1:0] is divided into a plurality of data blocks and dummy bits are inserted into bit positions of missing bits in the data blocks BD [L−1:0].

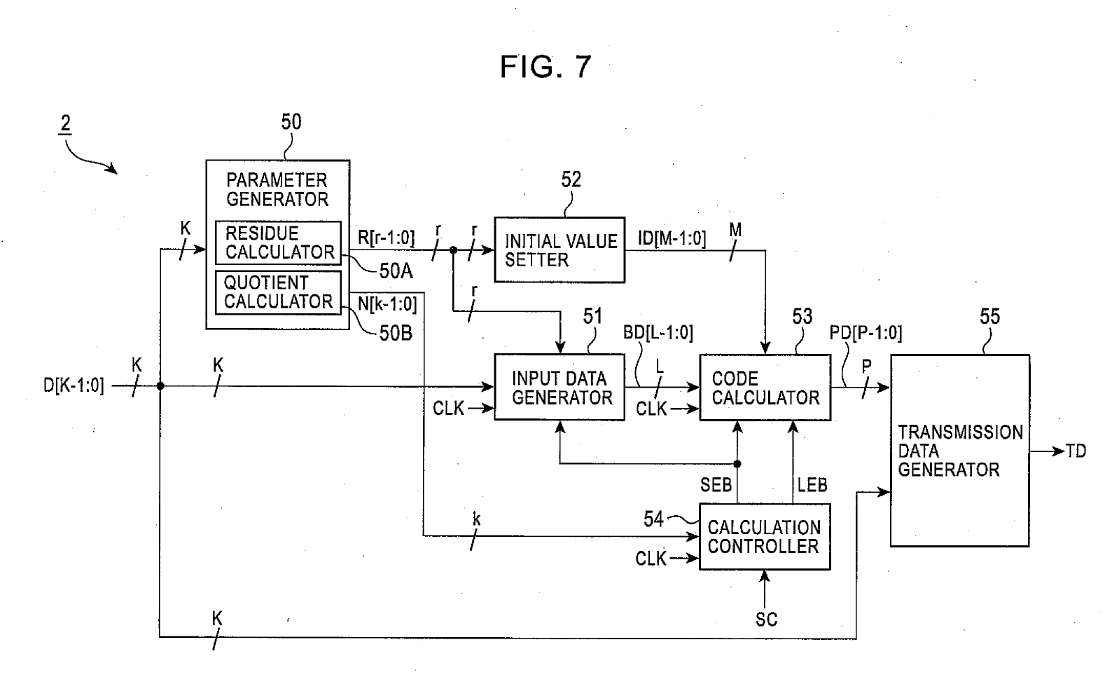

The code error detector 1 can be used for an encoder provided at the transmitting side. FIG. 7 is a block diagram of an error detecting code generator 2 which is an encoder provided at the transmitting side. As shown in FIG. 7, the error detecting code generator 2 includes a parameter generator 50, an input data generator 51, an initial value setter 52, a code calculator 53, a calculation controller 54, and a transmission data generator 55. The error detecting code generator 2 is embedded in a transmitter.

The input data generator 51 divides K-bit data D [K−1:0] to be transmitted into a plurality of data blocks, each of which includes the same number of information bits as the number of parallel processes L of the code calculator 53 (where L is a positive integer greater than one), and sequentially transmits each data block BD [L−1:0] to the code calculator 53. The code calculator 53 performs parallel calculations, based on a generator polynomial G(x), on the data blocks to generate check bits. That is, the code calculator 53 receives, as a parallel input, L information bits BD [L−1], BD [L−2], . . . , BD [0] of each data block BD [L−1:0] supplied from the input data generator 51 and then performs a parallel calculation on the data block to generate check bits PD [P−1], PD [P−2], . . . , PD [0].

The code calculator 53 has a divider circuit including a shift register (not shown). This shift register has M delay elements (where M is a positive integer), at least one modulo-2 adder (exclusive OR operator), and a feedback connection. The M delay elements shift the parallel-input information bits BD [L−1], BD [L−2], . . . , BD [0] in parallel synchronously with an operating clock CLK. The information bits BD [L−1], BD [L−2], . . . , BD [0], which are sent in parallel to the code calculator 53, represent coefficients of a polynomial P(x) (=M(x)·x^{n-k}) that is the product of an information polynomial M(x) and x^{n-k}. Residue calculation is performed through shift operations of the shift register in such a manner that the polynomial P(x) is divided by the generator polynomial G(x) to obtain a residue polynomial R(x). As a result of this residue calculation, the group of delay elements of the shift register holds check bits which represent coefficients of the residue polynomial R(x). The code calculator 53 supplies P-bit data PD [P−1:0] including these check bits to the transmission data generator 55. The transmission data generator 55 adds the check bits to the information bits to generate transmission data TD which is a codeword sequence having a code length of “K+P” and an information length of “K”. The transmission data TD is transmitted after being modulated through a modulator (not shown).

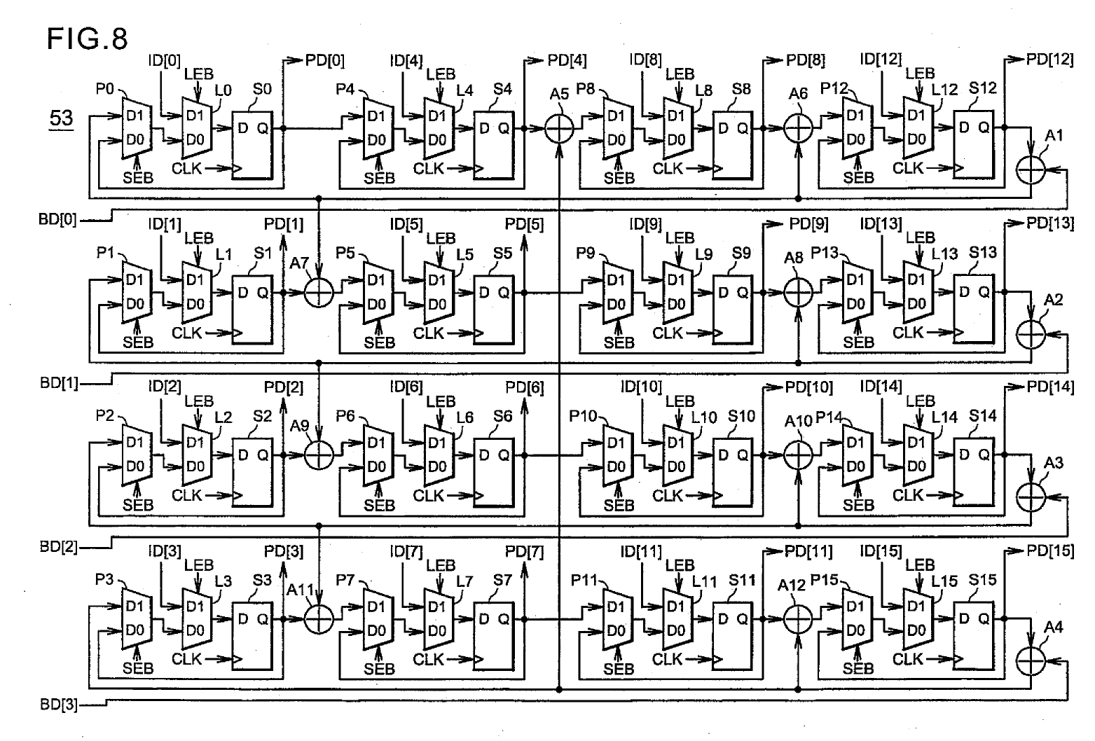

Referring to FIG. 8, an operation of the code calculator 53 when the number of parallel processes is 4 and the generator polynomial G(x) is x¹⁶+x¹²+x⁵+1 will be described. The code calculator 53 receives the 0th (least significant) to 3rd bits BD [0] to BD [3] of a data block BD [3:0] as a parallel input. Specifically, the 0th (least significant) bit BD [0] is introduced to an adder A1, the 1st bit BD [1] is introduced to an adder AZ, the 2nd bit [2] is introduced to an adder A3, and the 3rd bit BD [3] is introduced to an adder A4.

The configuration of the code calculator 53 shown in FIG. 8 is similar to that of the code calculator 13 provided at the receiving side shown in FIG. 2. Specifically, in the code calculator 53 of FIG. 8, four delay elements (flip-flops) S0, S4, S8, and S12 are connected in cascade via selectors P0, L0, P4, L4, PB, L8 P12, and L12 and modulo-2 adders A5 and A6. A feedback connection is provided to feed an output of the delay element S12 to the delay element S0, the adder A6, and an adder A7 via the adder A1. Another four delay elements (flip-flops) S1, S5, S9, and S13 are connected in cascade via selectors P1, L1, P5, L5, P9, L9, P13, and L13 and modulo-2 adders A7 and A8. A feedback connection is provided to feed an output of the delay element S13 to the delay element S1, the adder A8, and an adder A9 via the adder A2. Another four delay elements (flip-flops) S2, S6, S10, and S14 are connected in cascade via selectors P2, L2, P6, L6, P10, L10, P14, and L14 and modulo-2 adders A9 and A10. A feedback connection is provided to feed an output of the delay element S14 to the delay element S2, the adder A10, and an adder A11 via the adder A3. Another four delay elements (flip-flops) S3, S7, S11, and S15 are connected in cascade via selectors P3, L3, P7, L7, P11, L11, P15, and L15 and modulo-2 adders A11 and A12. A feedback connection is provided to feed an output of the delay element S15 to the delay element S3, the adder A12, and the adder A5 via the adder A4.

The parameter generator 50 of FIG. 7 detects a bit length “K” of the data to be transmitted D [K−1:0]. The parameter generator 50 includes a residue calculator 50A and a quotient calculator SOB. The residue calculator 50A calculates a residue by dividing the bit length “K” by the number of parallel processes L. The quotient calculator 50B calculates a quotient by dividing the bit length “K” by the number of parallel processes L. The r-bit residue data R [r−1:0] representing the residue of the division is supplied to the initial value setter 52 and the input data generator 51, while k-bit quotient data N [k−1:0] representing the quotient of the division is supplied to the calculation controller 54.

The initial value setter 52 has an initial value table (conversion table) that stores fixed-length bit sequences corresponding respectively to possible values of the residue data R [r−1:0]. Before parallel calculations of the code calculator 53, the initial value setter 52 refers to the initial value table and selects a fixed-length bit sequence corresponding to the value of the residue data R [r−1:0]. The initial value setter 52 then sends the selected fixed-length bit sequence (i.e., initial value data ID [M−1:0]) to the code calculator 53. The code calculator 53 performs parallel calculations after performing initial setting by storing the initial value data ID [M−1:0] in the group of delay elements of the shift register. The value of the residue data R [r−1:0] represents the bit length of missing bits that may be lost in a data block BD [L−1:0] generated by the input data generator 51. The code calculator 53 outputs an erroneous detection result if it performs parallel calculations on a group of data blocks having missing bits since the value of the missing bits is not constant. To prevent such erroneous detection, the input data generator 51 inserts the same bit length (i.e., the same number) of dummy bits as the value of the residue data R [r−1:0] into bit positions of the missing bits.

Before performing parallel calculations, it is necessary to perform initial setting by storing an initial value that matches the dummy bits in the delay element group of the shift register of the code calculator 53. The initial value setter 52 selects the initial value according to the length of the dummy bits. In the CRC scheme, such initial values are set to match initial values stored in the initial value setter 12 (see FIG. 1) of the code error detector 1 at the receiving side. The same initial value table is stored in both the initial value setter 12 of FIG. 1 and the initial value setter 52 of FIG. 7 when the code error detector 1 of the receiving side and the error detecting code generator 2 of the transmitting side have the same number of parallel processes and use the same dummy bit values.

The calculation controller 54 is similar to the calculation controller 14 (FIG. 6) of the code error detector 1 provided at the receiving side. Specifically, the calculation controller 54 has a controller similar to the initial setting controller 40, another controller similar to the timing controller 41, and a circuit similar to the counter circuit 42. Accordingly, the calculation controller 54 generates an initial setting control signal LEB having a logic level (for example, a high level) which enables initial setting of the code calculator 53 in response to a calculation start command SC received from a host controller (not shown). After the initial setting is completed, i.e., after a certain processing cycle(s) is (are) finished, the calculation controller 54 switches the logic level of the initial setting control signal LEB from the enable level to a disable level (for example, a low level) which disables the initial setting. When the initial setting control signal LEB switches to the disable level, the input data generator 51 stops supplying the data blocks BD [L−1:0] to the code calculator 53 in response to the shift control signal SEB having the disable level received from the calculation controller 54. The code calculator 53 stops parallel calculations in response to the shift control signal SEB having the disable level received from the calculation controller 54. Accordingly, shift operations of the shift register in the code calculator 53 are enabled over processing cycles according to the number of calculations.

As described above, even when the data to be transmitted D [K−1:0] has a variable or prime bit length, the error detecting code generator 2 of this embodiment can generate an error correcting code for the data to be transmitted D [K−1:0], regardless of the bit length of the data to be transmitted D [K−1:0]. This is because the data to be transmitted D [K−1:0] is divided into a plurality of data blocks and dummy bits are inserted into bit positions of missing bits in the data blocks BD [L−1:0].

Although the above-described embodiments employ the CRC scheme, the invention is not limited in this regard. The invention can be applied to any system which detects errors or generates error detection codes by performing a parallel calculation for a plurality of bits received as a parallel input.

It should also be noted that the preferred embodiments of the present invention have been disclosed for illustrative purposes, and those skilled in the art will appreciate that various modifications, additions and substitutions are possible, without departing from the scope and spirit of the invention as disclosed in the accompanying claims.

This application is based on Japanese Patent Application No. 2007-260644 filed on Oct. 4, 2007 and the entire disclosure thereof is incorporated herein by reference.

What is claimed is:

1. A code error detector for detecting a code error in received data, comprising:
an input data generator for dividing the received data into a plurality of data blocks, each including the same number of code bits as a predetermined number of parallel processes, and sequentially generating the plurality of data blocks; and
a code calculator for receiving, as a parallel input, the code bits of each of the data blocks sequentially supplied from the input data generator and applying a parallel calculation based on a predetermined generator polynomial on the data blocks to perform an error detection process,
wherein, when any of the data blocks has at least one missing bit, the input data generator inserts at least one dummy bit into a bit position of the at least one missing bit.

2. The code error detector according to claim 1, further comprising a residue calculator for calculating a residue by dividing a bit length of the received data by the predetermined number of parallel processes,
wherein, when the calculated residue has a value other than zero, the input data generator inserts, as the at least one dummy bit, the same bit length of bits as a bit length of the value of the calculated residue into the bit position of the at least one missing bit.

3. The code error detector according to claim 2, wherein, when the residue calculated by the residue calculator has a value other than zero, the input data generator allocates the at least one missing bit to a first data block among the plurality of data blocks.

4. The code error detector according to claim 2, further comprising an initial value setter including a conversion table that stores fixed-length bit sequences corresponding respectively to a plurality of bit lengths,
wherein, before the parallel calculation is applied, the initial value setter selects a fixed-length bit sequence corresponding to the bit length of the value of the residue data calculated by the residue calculator with reference to the conversion table, and
wherein the code calculator is a shift register including:
a plurality of delay elements for shifting the code bits received as the parallel input synchronously with an operating clock;
at least one exclusive OR operator; and
a selection circuit for storing a value of the fixed-length bit sequence selected by the initial value setter in the plurality of delay elements before the parallel calculation is performed.

5. The code error detector according to claim 4, further comprising:
a quotient calculator for calculating a quotient by dividing the bit length of the received data by the predetermined number of parallel processes; and
a calculation controller for setting the number of calculations to the calculated quotient and generating a control signal that enables a shift operation of the shift register over processing cycles according to the set number of calculations.

6. The code error detector according to claim 4, wherein the delay element is a flip-flop.

7. The code error detector according to claim 1, wherein the bit length of the received data is a variable bit length.

8. The code error detector according to claim 1, wherein the bit length of the received data is a prime bit length.

9. The code error detector according to claim 1, wherein the code is a cyclic redundancy check code.

10. An error detecting code generator for generating a codeword sequence that allows detection of a code error in transmission data, the error detecting code generator comprising:
an input data generator for dividing data to be transmitted into a plurality of data blocks, each including the same number of information bits as a predetermined number of parallel processes, and sequentially generating the data blocks;
a code calculator for receiving, as a parallel input, the information bits of each of the data blocks sequentially supplied from the input data generator and applying a parallel calculation based on a predetermined generator polynomial on the data blocks to generate check bits; and
a transmission data generator for generating a codeword sequence including the information bits and check bits,
wherein, when any of the data block has at least one missing bit, the input data generator inserts at least one dummy bit into a bit position of the at least one missing bit.

11. The error detecting code generator according to claim 10, further comprising a residue calculator for calculating a residue by dividing a bit length of the data to be transmitted by the predetermined number of parallel processes,
wherein, when the calculated residue has a value other than zero, the input data generator inserts, as the at least one dummy bit, the same bit length of bits as a bit length of the value of the calculated residue into the bit position of the at least one missing bit.

12. The error detecting code generator according to claim 11, wherein when the residue calculated by the residue calculator has a value other than zero, the input data generator allocates the at least one missing bit to a first data block among the plurality of data blocks.

13. The error detecting code generator according to claim 11 further comprising an initial value setter including a conversion table that stores fixed-length bit sequences corresponding respectively to a plurality of bit lengths,
wherein before the parallel calculation is performed, the initial value setter selects a fixed-length bit sequence corresponding to the bit length of the value of the residue data calculated by the residue calculator with reference to the conversion table, and
wherein the code calculator is a shift register including:
a plurality of delay elements for shifting the information bits received as the parallel input synchronously with an operating clock;
at least one exclusive OR operator; and
a selection circuit for storing a value of the fixed-length bit sequence selected by the initial value setter in the plurality of delay elements before the parallel calculation is performed.

14. The error detecting code generator according to claim 13, further comprising:
a quotient calculator for calculating a quotient by dividing the bit length of the data to be transmitted by the predetermined number of parallel processes; and
a calculation controller for setting the number of calculations to the calculated quotient and generating a control signal that enables a shift operation of the shift register over processing cycles according to the set number of calculations.

15. The error detecting code generator according to claim 13, wherein the delay element is a flip-flop.

16. The error detecting code generator according to claim 10, wherein the bit length of the data to be transmitted is a variable bit length.

17. The error detecting code generator according to claim 10, wherein the bit length of the data to be transmitted is a prime bit length.

18. The error detecting code generator according to claim 10, wherein the code is a cyclic redundancy check code.
